(19) United States
(12) Patent Application Publication
(10) Pub. No.: US 2022/0358363 A1
(43) Pub. Date: Nov. 10, 2022

(54) ENGINE SURGE FAULT PREDICTION SYSTEM AND METHOD BASED ON FUSION NEURAL NETWORK MODEL

(71) Applicant: SOUTHWEST PETROLEUM UNIVERSITY, Chengdu, SC (CN)

(72) Inventors: DeSheng ZHENG, Chengdu (CN); XiaoLan TANG, Chengdu (CN); XinLong WU, Chengdu (CN); BiYing DENG, Chengdu (CN); KeXin ZHANG, Chengdu (CN); DongPu JIANG, Chengdu (CN)

(21) Appl. No.: 17/623,601

(22) PCT Filed: Sep. 15, 2021
(86) PCT No.: PCT/CN2021/118455

§ 371 Date: Dec. 29, 2021

(30) Foreign Application Priority Data
Sep. 30, 2020 (CN) 202011056637.4

(51) Int. Cl. G06N 3/08; G06N 5/02

(52) U.S. Cl. CPC G06N 3/08; G06N 5/022

(57) ABSTRACT

The invention claims an engine surge fault prediction system and method based on fusion neural network model, belonging to the technical field of time series data prediction. The system comprises a prediction module, used for generating prediction time series with a specified length through 3D structure time series data of the engine; a feature extraction module, used for extracting the local features of the prediction time series, semantic relations among data, and overall trend features of the series; a classification module, used for judging if there is a surge fault according to the local features of the prediction time series, semantic relations among data, and overall trend features of the series.

### TECHNICAL FIELD

The invention relates to the technical field of time series data prediction, in particular to an engine surge fault prediction system and method based on fusion neural network model.

### BACKGROUND

The aero-engine is the “heart” of the aircraft, and engine faults account for a large proportion of flight faults. Once such a fault occurs, it will be very fatal. Therefore, how to predict aero-engine faults in advance is a difficult problem to be solved in current flight safety. The surge fault of an aero-engine is a common abnormal working state, which will cause severe vibration of engine parts and overtemperature of the hot end, and even endanger flight safety in severe cases. Therefore, it is one of the important prerequisites for avoiding flight accidents to find and identify the surge phenomenon in time when the engine is about to surge and then take anti-surge measures.

At present, the research on fault prediction methods presents a diversified trend. They are mainly divided into model-based, knowledge-based and data-based prediction methods.

1. Model-based prediction: mainly includes failure physical model and system-based input/output model. Although these methods can meet the real-time requirements, it is very difficult to establish a prediction model because the engine itself is a complex nonlinear vibration system.

2. Knowledge-based prediction: it can give full play to the expert knowledge and experience of various engine disciplines without an accurate mathematical model. However, due to the limited fault modes covered by the expert knowledge base, there are still many problems to be solved in practical application.

3. Data-based prediction: its greatest advantage is that the prediction is conducted on the basis of data by mining the hidden information in the data without accurate mathematical and physical models of engines. The fault prediction technology based on machine learning and deep learning models has gradually become the mainstream method at present. Especially, the method of building a neural network model based on deep learning to complete the engine fault prediction can automatically learn the predictive features directly through the network model built without relying on previous assumptions and processing the original data.

Furthermore, as the aero-engine sensor data belongs to time series data, the prediction of aero-engine sensor data can be regarded as a time-series data prediction problem. Traditional time series prediction methods mainly include linear models such as AR, MR, ARMA, and ARIMA, which have good effects on stationary time series prediction. However, most of the stock market data, hydrological data, or the aero-engine sensor data mentioned herein have nonlinear features, so it is difficult to get better prediction results through the traditional linear prediction.

At present, there are not many solutions to predict the time series data such as aero-engine sensor data in the industry. Most of them are based on the aero-engine sensor data to solve the problems regarding the remaining life prediction or fault diagnosis of aero-engines. In addition, there are very few solutions that use machine learning algorithms or build deep learning models to make predictions based on data, and most of them are based on models or knowledge, which not only takes time and effort, but also has low accuracy.

### SUMMARY

The purpose of the invention is to bridge the technical gap of data-based prediction in the field of aero-engine surge fault prediction, to predict faults more accurately and quickly in advance, and to provide an engine surge fault prediction system and method based on fusion neural network model.

The purpose of the invention is realized through the following technical solution: an engine surge fault prediction system based on fusion neural network model, which specifically comprises:

A prediction module, used for generating prediction time series with a specified length through 3D structure time series data of the engine; a feature extraction module, used for extracting the local features of the prediction time series, semantic relations among data, and overall trend features of the series; a classification module, used for judging if there is a surge fault according to the local features of the prediction time series, semantic relations among data, and overall trend features of the series.

As an option, the prediction module comprises the first LSTM layer and the second LSTM layer connected in sequence; the first LSTM layer is used as an encoder for encoding the 3D structure time series data of the engine into a batch of 2D semantic vectors; the second LSTM layer is used as a decoder for decoding the 2D semantic vectors into the prediction time series with a specified length.

As an option, the feature extraction module comprises the 1D convolution unit and the third LSTM layer connected in sequence; the 1D convolution unit is used for extracting the local features of the prediction time series; the third LSTM layer is used for extracting the semantic relations among data in the prediction time series and the overall trend features of the series.

As an option, the 1D convolution unit specifically comprises two 1D convolution layers connected in sequence with a stride of 1.

As an option, the classification module comprises the first fully connected layer and the second fully connected layer connected in sequence; the first fully connected layer is used for carrying out weighted mapping of the local features of the prediction time series, semantic relations among data, and overall trend feature information of the series; the second fully connected layer is used for binarizing the weighted mapped feature information and judging whether the engine will have a surge fault in a future period of time.

The invention also relates to an engine surge fault prediction method based on fusion neural network model, which comprises the following steps:

Generating prediction time series with a specified length through 3D structure time series data of the engine;

Extracting the local features of the prediction time series, semantic relations among data, and overall trend features of the series;

Judging if there is a surge fault according to the local features of the prediction time series, semantic relations among data, and overall trend features of the series.

As an option, judging if there is a surge fault according to the local features of the prediction time series, semantic relations among data, and overall trend features of the series is specifically as follows:

Carrying out weighted mapping of the local features of the prediction time series, semantic relations among data, and overall trend feature information of the series; binarizing the weighted mapped feature information and judging whether the engine will have a surge fault in a future period of time.

As an option, binarizing the weighted mapped feature information is specifically as follows:

Using the Sigmoid activation function to judge whether the engine will have a surge fault in a future period of time, with the function of:

$$S ( x ) = \frac{1}{1 + {e}^{- x}}$$

Where, x represents the linear combination of the weighted mapped feature information.

As an option, the method also comprises data preprocessing steps:

Using the sliding window algorithm to intercept the subsequences of data from different engine monitoring devices to obtain the subsequence set; taking one subsequence in the subsequence set as the dividing point subsequence, the subsequence before the dividing point subsequence as the training set, and the subsequence after the dividing point subsequence as the test set.

As an option, the method also comprises backpropagation training steps:

Using the binary cross entropy function as the loss function for backpropagation training to obtain the gradient of the weight coefficient of each network layer in the model on which the prediction method is based, and then updating the weight coefficient of each network layer; loss function:

$$L = \frac{1}{N} \cdot {\sum }_{i} - [ {y}_{i} \cdot log ( {p}_{i} ) + ( 1 - {y}_{i} ) \cdot log ( 1 - {p}_{i} ) ]$$

Where, p₁ represents the probability that the prediction result obtained from sequence i shows a surge fault; yᵢ represents the label value of sample i, and N indicates the number of samples.

It should be further explained that the technical features corresponding to each option for the above system or method can be combined or replaced with each other to form a new technical solution.

Compared with the prior art, the invention has the following beneficial effects:

(1) According to the invention, the prediction time series with a specified length is generated through 3D structure time series data of the engine by using the prediction module of the system, that is, the prediction of the working state data of the engine in a future period of time is achieved, and then, the local features of the prediction time series, semantic relations among data, and overall trend features of the series are extracted and classified by using the feature extraction module and classification module, and whether the working state data of the engine in a future period of time include surge fault data is judged, so that the engine surge fault is predicted more accurately and quickly in advance.

(2) According to the invention, the local features of the prediction time series are extracted through the 1D convolution unit, and the semantic relations among data in the prediction time series and the overall trend features of the series are extracted through the third LSTM layer, so that more comprehensive feature information of the engine time series data is obtained, which is conducive to improving the accuracy of data classification.

(3) According to the invention, the 1D convolution unit specifically comprises two 1D convolution layers connected in sequence with a stride of 1. On the basis of not using the pooling layer to extract feature information, more feature information can be retained, which improves the precision and recall of the system.

(4) With the method herein, the prediction time series with a specified length is generated through 3D structure time series data of the engine, that is, the prediction of the working state data of the engine in a future period of time is achieved, and then, the local features of the prediction time series, semantic relations among data, and overall trend features of the series are extracted and classified by using the feature extraction module and classification module, and whether the working state data of the engine in a future period of time include surge fault data is judged, so that the engine surge fault is predicted more accurately and quickly in advance.

(5) The invention uses the Sigmoid activation function to judge whether the engine will have a surge fault in a future period of time and maps the surge fault of the engine into the interval of (0, 1), which is suitable for the prediction scenario for judging whether the engine will have a surge fault in a future period of time.

(6) The invention uses the sliding window algorithm to intercept the subsequences of data from different engine monitoring devices to obtain a large number of subsequences and form a subsequence set, which is beneficial for training the prediction model and improving the prediction accuracy of the model; the training set and the test set are divided based on the dividing point subsequence, so as to prevent the introduction of future data from causing over-fitting phenomenon in the process of model training and affecting the final prediction effect of the model.

(7) The invention uses the binary cross entropy function as the loss function for backpropagation training and updates the weight coefficient of each network layer.

### BRIEF DESCRIPTION OF DRAWINGS

A further detailed description is made below to the specific embodiments in combination with drawings. The drawings described herein are used to help further understand the invention and constitute a part of the invention. In the drawings, the same reference marks are used to indicate the same or similar parts. The exemplary embodiments and corresponding descriptions hereof do not constitute improper limitations but for explaining the invention.

FIG. 1 is a system chart of Embodiment 1;

FIG. 2 is a block diagram of the prediction module of Embodiment 1;

FIG. 3 is a comparison diagram of the prediction curve and the real data curve of the prediction module of Embodiment 1;

FIG. 4 is a block diagram of the 1D convolution unit of Embodiment 1;

FIG. 5 is a comparison diagram of the system prediction curve and the real data curve of Embodiment 1.

### DETAILED DESCRIPTION

The following is a clear and complete description of the technical solution of the invention in combination with the drawings. Obviously, the embodiments are only some of rather than all of the embodiments of the invention. All other embodiments obtained by those of ordinary skill in the art based on the embodiments of the invention without creative efforts shall fall into the protection scope of the invention.

It should be noted that the directions or position relationships such as “central”, “upper”, “lower”, “left”, “right”, “vertical”, “horizontal”, “inside”, and “outside” in the description of the invention are based on those on drawings, and are used only for facilitating the description of the invention and for simplified description, not for indicating or implying that the target devices or components must have a special direction and be structured and operated at the special direction, therefore, they cannot be understood as the restrictions to the invention. Moreover, the words “first” and “second” are used only for description, and cannot be understood as an indication or implication of relative importance.

It should be noted in the description of the invention that unless otherwise specified or restricted, the words “installation”, “interconnection” and “connection” shall be understood in a general sense. For example, the connection may be a fixed connection, removable connection, integrated connection, mechanical connection, electrical connection, direct connection, indirect connection through intermediate media, or connection between two components. Persons of ordinary skill in the art of the invention can understand the specific meanings of the terms above in the invention as the case may be.

Moreover, the technical characteristics involved in different embodiments of the invention as described below can be combined together provided there is no discrepancy among them.

The invention relates to an engine surge fault prediction system and method based on fusion neural network model. The system has prediction and classification functions, and finally realizes the advance prediction of the aero-engine surge fault through the classification step of predicting the future sensor data and then judging whether there is a surge.

### Embodiment 1

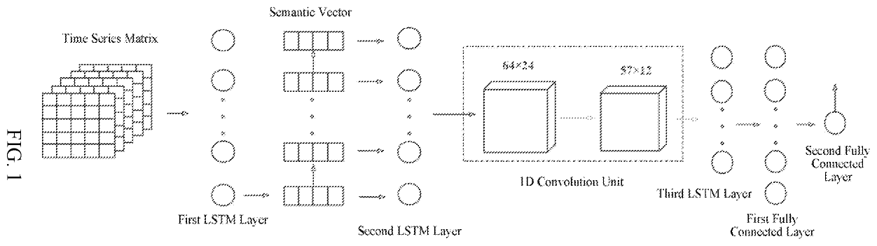

As shown in FIG. 1, in Embodiment 1 of the engine surge fault prediction system based on fusion neural network model, the system based on fusion neural network (PCFNN) of the invention specifically comprises a prediction module, a feature extraction module, and a classification module connected in sequence. Specifically, the prediction module is used for generating prediction time series with a specified length through 3D structure time series data of the engine; the feature extraction module is used for extracting the local features of the prediction time series, semantic relations among data, and overall trend features of the series; the classification module is used for judging if there is a surge fault according to the local features of the prediction time series, semantic relations among data, and overall trend features of the series. According to the invention, the prediction time series (prediction sequence matrix) with a specified length is generated through 3D structure time series data (time series matrix) of the engine by using the prediction module of the system, that is, the prediction of the working state data of the engine in a future period of time is achieved, and then, the local features of the prediction time series, semantic relations among data, and overall trend features of the series are extracted and classified by using the feature extraction module and classification module, and whether the working state data of the engine in a future period of time include surge fault data is judged, so that the engine surge fault is predicted more accurately and quickly in advance. Compared with the neural network model in which the convolution layer and the LSTM layer are connected in sequence in the prior art, the invention can predict whether a surge fault will occur in a future period of time, instead of being limited to the fault diagnosis of historical data, and has a broader application prospect.

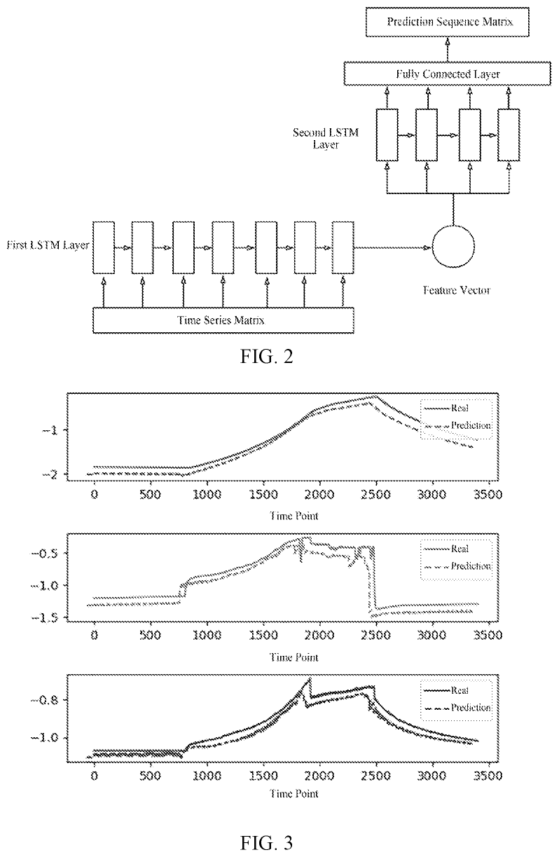

Furthermore, as shown in FIG. 2, the prediction module comprises the first LSTM layer and the second LSTM layer connected in sequence; the first LSTM layer is used as an encoder for encoding the 3D structure time series data of the engine into a batch of 2D semantic vectors; the second LSTM layer is used as a decoder for decoding the 2D semantic vectors into the prediction time series with a specified length. More specifically, the batch of 2D semantic vectors is output by the last cell in the first LSTM layer, representing the semantic features of the current entire input sequence, and then the semantic vectors are copied to make the current sequence length equal to the output sequence length, so as to ensure the precision of data prediction. Decoding the 2D semantic vectors with a specified length into a prediction time series with a specified length can be achieved by setting the number of cells in the LSTM decoder. In another word, by setting different numbers of LSTM cells, a prediction time series with a specified length can be generated, and finally, the working state data value of the aero-engine in a future period of time can be obtained. More specifically, the prediction module also comprises a fully connected layer, which is connected with the second LSTM layer and is used to output the number of neurons in each cell unit in the output 3D vector to the number corresponding to the feature number of each time point of the required time series data through dimension transformation. It should be noted that the feature information output by the second LSTM layer is a 3D vector comprising the number of bulk data for training, the number of time steps (sequence length), and the number of neurons in each cell unit. The third dimension, i.e. the number of neurons in each cell unit, generally represents the feature number of the time step data and here refers to the number of aero-engine detection devices at the current time point, i.e. the feature number at the current time point.

It should be further explained that instead of using activation functions such as Relu, Sigmoid, or Tan h in the selection of the activation function for the prediction module, the values are directly output. As the Tan h function is used by default in the LSTM layer to activate the final output, the Tan h function and the similar Sigmoid function are not used again. The Relu function itself is often used to avoid the frequent gradient disappearance in deep neural network training. However, the prediction module mentioned in the invention belongs to the shallow neural network, so there is no need to use the Relu function.

Furthermore, the feature extraction module comprises the 1D convolution unit and the third LSTM layer connected in sequence; specifically, after the prediction sequence matrix with a specified length is obtained, part of the input sequence is spliced and reconstructed with the prediction sequence as the input of the subsequent 1D convolution unit. The 1D convolution unit extracts the local features of the prediction time series and carries out feature analysis. The third LSTM layer extracts the semantic relations among data in the prediction time series and the overall trend features of the series, so as to obtain more comprehensive feature information of the engine time series data, which is beneficial to improving the accuracy of data classification.

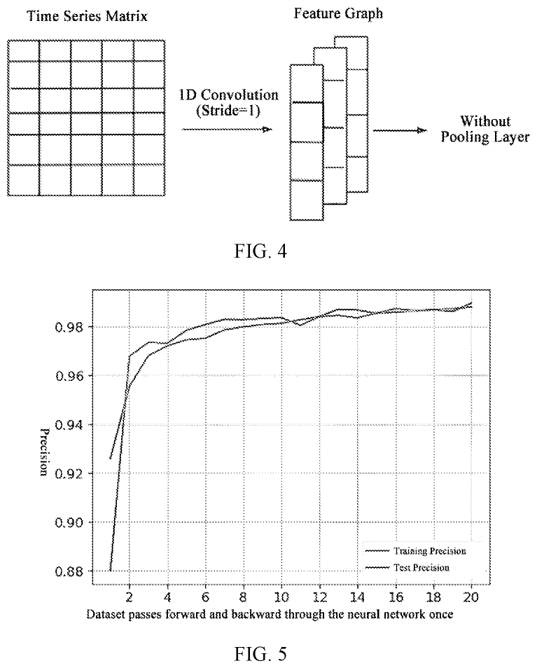

Furthermore, as shown in FIG. 4, the 1D convolution unit specifically comprises two 1D convolution layers connected in sequence with a stride of 1. On the basis of not using the pooling layer to extract feature information, more feature information can be retained, which improves the precision and recall rate of the system. More specifically, the two 1D convolution layers use the Relu activation function, allowing the output of some neurons to be 0, so as to keep the network sparse, reduce the interdependence between parameters and the probability of over-fitting, and decrease the amount of computation to speed up the training. It should be further explained that the traditional CNN architecture generally comprises a convolution layer+a pooling layer, wherein the convolution layer is responsible for extracting data features, and the pooling layer is responsible for further dimensionality reduction of the extracted feature information in order to further extract features, speed up training and reduce over-fitting. As an option, the traditional CNN architecture can also use skip convolution with a stride greater than 1 to replace the pooling layer. The formula for calculating the output size of any given convolution layer is as follows:

$$o = \frac{( w - k + 2 p )}{s} + 1$$

Where: o represents the data size output by the convolution layer; k represents the size of the convolution kernel; p represents the padding; s represents the stride. If s is greater than 1, the calculated size will be reduced by multiple, which also achieves the purpose of dimensionality reduction achieved by the pooling layer, but at the same time, the information of adjacent time points will be lost. Therefore, this is not suitable for feature extraction of time series data. The loss of information of adjacent time points will greatly reduce the prediction accuracy of the system. In order to further illustrate the advantages of applying the 1D convolution layer with a stride of 1 to time series data in the invention, a performance comparison test was conducted for the invention and the prior art that uses convolution+pooling with a stride greater than 1 (without pooling). The test results are shown in TABLE 1 below:

TABLE 1
Performance Comparison of Feature
Extraction of the Invention with the Prior Art

| Model | | | Weighted |
|---|---|---|---|
| Name/ | | | Average Based |
| Evaluation | | | on Precision and |
| Index | Precision | Recall | Recall |
| Convolution + pooling | 89.9% | 96.2% | 92.9% |
| Stride greater than 1 | 98.7 | 80% | 88.3% |
| 1 D convolution with | 95.7% | 93.6% | 94.7% |
| a stride of 1 | | | |

As shown in TABLE 1, the test results of the 1D convolution method with a stride of 1 and no pooling layer in the invention are all about 95% in the evaluation of the three indexes. Especially in the comprehensive index F1_Score of the reaction model in terms of recall and precision, the convolution in this solution with a stride of 1 and no pooling layer has achieved the best effect, reaching 94.7%.

Furthermore, the classification module comprises the first fully connected layer and the second fully connected layer connected in sequence; the first fully connected layer is used for carrying out weighted mapping of the local features of the prediction time series, semantic relations among data, and overall trend feature information of the series; the second fully connected layer is used for binarizing the weighted mapped feature information (local features of the prediction time series, semantic relations among data, and overall trend features of the series) and judging whether the engine will have a surge fault in a future period of time. More specifically, the first fully connected layer uses the Relu activation function, allowing the output of some neurons to be 0, so as to keep the network sparse, reduce the interdependence between parameters and the probability of over-fitting, and decrease the amount of computation to speed up the training. The second fully connected layer uses the Sigmoid activation function to binarize the weighted mapped feature information.

For further illustration, the performance of the system in the invention is compared with that of CNN, RNN, and LSTM models in terms of precision, recall, and the weighted average F1_Score based on the former two. The comparison results are shown in TABLE 2 below:

TABLE 2
Performance Comparison of PCFNN of
the Invention with Existing Models

| Model | | | Weighted |
|---|---|---|---|
| Name/ | | | Average Based |
| Evaluation | | | on Precision |
| Index | Precision | Recall | and Recall |
| RNN | 86.3% | 79.4% | 82.7% |
| CNN | 94.6% | 84.2% | 89.0% |
| LSTM | 92.5% | 86.2% | 89.2% |
| PCFNN | 95.7% | 93.6% | 94.7% |

It can be seen from TABLE 2 and FIG. 5 that the performance of the system based on fusion neural network (PCFNN) in the invention is obviously superior to that of the prior art so that the surge fault of the engine in a future period of time can be accurately predicted. With the increasing number of iterations, the precision of the training set and the test set generally shows an upward trend, and there will be no over-fitting phenomenon.

### Embodiment 2

This embodiment has the same inventive concept as Embodiment 1. On the basis of this embodiment, an engine surge fault prediction method based on fusion neural network model is provided, which comprises the following steps:

S1: generating prediction time series with a specified length through 3D structure time series data of the engine;

S2: extracting the local features of the prediction time series, semantic relations among data, and overall trend features of the series;

S3: judging if there is a surge fault according to the local features of the prediction time series, semantic relations among data, and overall trend features of the series.

Furthermore, Step S1, i.e. generating prediction time series with a specified length through 3D structure time series data of the engine, is specifically as follows:

S11: encoding the 3D structure time series data of the engine into a batch of 2D semantic vectors and encoding the vectors into 2D semantic vectors with a specified length; specifically, copying the semantic vectors to make the input sequence length equal to the output sequence length, so as to ensure the accuracy of data prediction.

S12: decoding the 2D semantic vectors with a specified length into a prediction time series with a specified length. Specifically, it can be achieved by setting the number of cells in the LSTM decoder. In another word, by setting different numbers of LSTM cells, a prediction time series with a specified length can be generated, and finally, the working state data value of the aero-engine in a future period of time can be obtained.

Furthermore, in Step S2, the local features of the prediction time series are extracted by using two 1D convolution layers connected in sequence with a stride of 1; the semantic relations among data in the prediction time series and the overall trend features of the series are extracted by using the LSTM layer. More specifically, the two 1D convolution layers use the Relu activation function, allowing the output of some neurons to be 0, so as to keep the network sparse, reduce the interdependence between parameters and the probability of over-fitting, and decrease the amount of computation to speed up the training. The Relu activation function formula is as follows:

$$R ( x ) = \{ \begin{matrix}0 , x \leq 0 \\ x , x > 0\end{matrix} \qquad ( 1 )$$

It should be further noted that the Relu function may cause network sparsity, so the first LSTM layer and the second LSTM layer do not use this activation function, to reserve more feature information for analysis and extraction by the 1D convolution layer.

Furthermore, Step S3, i.e. judging if there is a surge fault according to the local features of the prediction time series, semantic relations among data, and overall trend features of the series, is specifically as follows:

S31: carrying out weighted mapping of the local features of the prediction time series, semantic relations among data, and overall trend feature information of the series; specifically, a fully connected layer is used to carry out weighted mapping of the local features of the prediction time series, semantic relations among data, and overall trend feature information of the series. This fully connected layer uses the Relu activation function, allowing the output of some neurons to be 0, so as to keep the network sparse, reduce the interdependence between parameters and the probability of over-fitting, and decrease the amount of computation to speed up the training. For the formula of the Relu activation function, see the Relu activation function of the 1D convolution layer, which will not be described here.

S32: binarizing the weighted mapped feature information and judging whether the engine will have a surge fault in a future period of time. Specifically, the weighted mapped feature information is binarized through the fully connected layer to judge whether the engine will have a surge fault in a future period of time.

Furthermore, binarizing the weighted mapped feature information is specifically as follows:

S321: using the Sigmoid activation function to judge whether the engine will have a surge fault in a future period of time, with the function of:

$$S ( x ) = \frac{1}{1 + {e}^{- x}}$$

Where, x represents the linear combination of the weighted mapped feature information. The Sigmoid activation function can map the input data into the interval of (0, 1), which is suitable for the prediction scenario for judging whether the engine will have a surge fault in a future period of time.

Furthermore, there are data preprocessing steps prior to Step S1:

S01: using the sliding window algorithm to intercept the subsequences of data from different engine monitoring devices to obtain the subsequence set; specifically, using the sliding window algorithm to intercept the subsequences of data from different engine monitoring devices can obtain a large number of subsequences and form a subsequence set, which is beneficial for training the prediction model and improving the prediction accuracy of the model. As a specific embodiment, the slide is 1, the length of the subsequence corresponds to the length of the sliding window, and the window size is 64, wherein each time point in each sequence stores data (data of the engine working state) collected by different sensors (aero-engine monitoring devices).

S02: taking one subsequence in the subsequence set as the dividing point subsequence, the subsequence before the dividing point subsequence as the training set, and the subsequence after the dividing point subsequence as the test set, and standardizing the training set and the test set respectively. The training set and the test set are divided based on the dividing point subsequence, which will not cause a problem that the prediction effect of the prediction model is affected by the sorting of the randomly shuffled sequence data. It should be further explained that the training set and the test set are standardized respectively. In another word, the data distribution is converted into a standard normal distribution with a mean value of 0 and a standard deviation of 1, which is used to eliminate errors caused by different dimensions and large differences in numerical values, thereby accelerating the convergence of weight parameters and improving the training effect of the model.

Furthermore, backpropagation training steps are also included in the process of model training:

Using the binary cross entropy function as the loss function for backpropagation training to obtain the gradient of the weight coefficient of each network layer in the model on which the prediction method is based, and then updating the weight coefficient of each network layer until reaching the maximum iterations set; specifically, the loss function is as follows:

$$L = \frac{1}{N} \cdot {\sum }_{i} - [ {y}_{i} \cdot log ( {p}_{i} ) + ( 1 - {y}_{i} ) \cdot log ( 1 - {p}_{i} ) ]$$

Where, p₁ represents the probability that the prediction result obtained from sequence i shows a surge fault; yᵢ represents the label value of sample i, and N indicates the number of samples. The invention uses the binary cross entropy function as the loss function for backpropagation training and updates the weight coefficient of each network layer.

With the method herein, the prediction time series with a specified length is generated through 3D structure time series data of the engine, that is, the prediction of the working state data of the engine in a future period of time is achieved, and then, the local features of the prediction time series, semantic relations among data, and overall trend features of the series are extracted and classified by using the feature extraction module and classification module, and whether the working state data of the engine in a future period of time include surge fault data is judged, so that the engine surge fault is predicted more accurately and quickly in advance.

### Embodiment 3

This embodiment provides a storage medium with the same inventive concept as Embodiment 2, on which computer instructions are stored. When the computer instructions are running, the steps of the engine surge fault prediction method based on fusion neural network model in Embodiment 2 are implemented.

Based on such an understanding, the technical solution of this embodiment or the part that contributes to the prior art or the part of the technical solution can be embodied in the form of a software product, which is stored in a storage medium and includes several instructions causing a computer device (which can be a personal computer, a server, or a network device) to execute all or part of the steps of the method in each embodiment of the invention. The aforementioned storage medium includes the USB flash drive, mobile hard disk, read-only memory (ROM), random access memory (RAM), diskette or CD, and other media available for storage of program codes.

### Embodiment 4

This embodiment also provides a terminal, which has the same inventive concept as Embodiment 2, and comprises a memory and a processor, wherein the memory stores computer instructions that can be run on the processor. When the processor runs the computer instructions, the steps of the engine surge fault prediction method based on fusion neural network model in Embodiment 2 are implemented. The processor may be a single-core or multi-core central processing unit or a specific integrated circuit, or one or more integrated circuits configured to implement the invention.

Each functional unit in the embodiments provided by the invention may be integrated into one processing unit, or each unit may exist independently and physically, or two or more units may be integrated into one unit.

The above specific embodiments are detailed descriptions of the invention, and it could not be considered that the specific embodiments of the invention are only limited to these descriptions. Persons of ordinary skill in the art of the invention could also make some simple deductions and substitutions without departing from the concept of the invention, which should be deemed to fall within the protection scope of the invention.

1. The engine surge fault prediction system based on fusion neural network model, wherein the system comprises:
a prediction module, used for generating prediction time series with a specified length through 3D structure time series data of the engine, to achieve the prediction of the working state data of the engine in a future period of time;
a feature extraction module, used for extracting the local features of the prediction time series, semantic relations among data, and overall trend features of the series;
a classification module, used for judging if there is a surge fault according to the local features of the prediction time series, semantic relations among data, and overall trend features of the series;
the prediction module comprises the first LSTM layer and the second LSTM layer connected in sequence;
the first LSTM layer is used as an encoder for encoding the 3D structure time series data of the engine into a batch of 2D semantic vectors; the second LSTM layer is used as a decoder for decoding the 2D semantic vectors into the prediction time series with a specified length;
the batch of 2D semantic vectors is output by the last cell in the first LSTM layer, representing the semantic features of the current entire input sequence, and then the 2D semantic vectors are copied to make the current sequence length equal to the output sequence length, so as to ensure the precision of data prediction; the 2D semantic vectors with a specified length are decoded into a prediction time series with a specified length, which can be generated by setting different numbers of LSTM cells, to finally obtain the working state data value of the aero-engine in a future period of time.

2. The engine surge fault prediction system based on fusion neural network model according to claim 1, wherein the feature extraction module comprises the 1D convolution unit and the third LSTM layer connected in sequence;
the 1D convolution unit is used for extracting the local features of the prediction time series; the third LSTM layer is used for extracting the semantic relations among data in the prediction time series and the overall trend features of the series.

3. The engine surge fault prediction system based on fusion neural network model according to claim 2, wherein the 1D convolution unit specifically comprises two 1D convolution layers connected in sequence with a stride of 1.

4. The engine surge fault prediction system based on fusion neural network model according to claim 1, wherein the classification module comprises the first fully connected layer and the second fully connected layer connected in sequence;
the first fully connected layer is used for carrying out weighted mapping of the local features of the prediction time series, semantic relations among data, and overall trend feature information of the series; the second fully connected layer is used for binarizing the weighted mapped feature information and judging whether the engine will have a surge fault in a future period of time.

5. The engine surge fault prediction method based on fusion neural network model, wherein the method comprises the following steps:
generating prediction time series with a specified length through 3D structure time series data of the engine; generating prediction time series with a specified length through 3D structure time series data of the engine is achieved by a prediction module, which comprises the first LSTM layer and the second LSTM layer connected in sequence; the first LSTM layer is used as an encoder for encoding the 3D structure time series data of the engine into a batch of 2D semantic vectors; the second LSTM layer is used as a decoder for decoding the 2D semantic vectors into the prediction time series with a specified length;
the batch of 2D semantic vectors is output by the last cell in the first LSTM layer, representing the semantic features of the current entire input sequence, and then the 2D semantic vectors are copied to make the current sequence length equal to the output sequence length, so as to ensure the precision of data prediction; the 2D semantic vectors with a specified length are decoded into a prediction time series with a specified length, which can be generated by setting different numbers of LSTM cells, to finally obtain the working state data value of the aero-engine in a future period of time;
extracting the local features of the prediction time series, semantic relations among data, and overall trend features of the series;
judging if there is a surge fault according to the local features of the prediction time series, semantic relations among data, and overall trend features of the series.

6. The engine surge fault prediction method based on fusion neural network model according to claim 5, wherein judging if there is a surge fault according to the local features of the prediction time series, semantic relations among data, and overall trend features of the series is specifically as follows:
carrying out weighted mapping of the local features of the prediction time series, semantic relations among data, and overall trend feature information of the series;
binarizing the weighted mapped feature information and judging whether the engine will have a surge fault in a future period of time.

7. The engine surge fault prediction method based on fusion neural network model according to claim 6, wherein binarizing the weighted mapped feature information is specifically as follows:
using the Sigmoid activation function to judge whether the engine will have a surge fault in a future period of time, with the function of:
$$S ( x ) = \frac{1}{1 + {e}^{- x}}$$
where, x represents the linear combination of the weighted mapped feature information.

8. The engine surge fault prediction method based on fusion neural network model according to claim 5, wherein the method also comprises data preprocessing steps:
using the sliding window algorithm to intercept the subsequences of data from different engine monitoring devices to obtain the subsequence set;
taking one subsequence in the subsequence set as the dividing point subsequence, the subsequence before the dividing point subsequence as the training set, and the subsequence after the dividing point subsequence as the test set.

9. The engine surge fault prediction method based on fusion neural network model according to claim 5, wherein the method also comprises backpropagation training steps:
using the binary cross entropy function as the loss function for backpropagation training to obtain the gradient of the weight coefficient of each network layer in the model on which the prediction method is based, and then updating the weight coefficient of each network layer; loss function:
$$L = \frac{1}{N} \cdot {\sum }_{i} - [ {y}_{i} \cdot log ( {p}_{i} ) + ( 1 - {y}_{i} ) \cdot log ( 1 - {p}_{i} ) ]$$
where, p₁ represents the probability that the prediction result obtained from sequence i shows a surge fault; yᵢ represents the label value of sample i, and N indicates the number of samples.
